(19) United States
(12) Patent Application Publication
(10) Pub. No.: US 2022/0231481 A1
(43) Pub. Date: Jul. 21, 2022

(54) ELECTRICALLY DRIVEN ORGANIC SEMICONDUCTOR LASER DIODE, AND METHOD FOR PRODUCING SAME

(71) Applicants: KYUSHU UNIVERSITY, NATIONAL UNIVERSITY CORPORATION, Fukuoka-shi, Fukuoka (JP); KOALA Tech Inc., Fukuoka-shi, Fukuoka (JP)

(72) Inventors: Sangarange Don Atula SANDANAYAKA, Fukuoka-shi, Fukuoka (JP); Toshinori MATSUSHIMA, Fukuoka-shi, Fukuoka (JP); Fatima BENCHEIKH, Fukuoka-shi, Fukuoka (JP); Jean-Charles RIBIERRE, Fukuoka-shi, Fukuoka (JP); Ryutaro KOMATSU, Fukuoka-shi, Fukuoka (JP); Shinobu TERAKAWA, Fukuoka-shi, Fukuoka (JP); Jong Uk KIM, Fukuoka-shi, Fukuoka (JP); Adikari Mudiyanselage Chathuranganie SENEVIRATHNE, Fukuoka-shi, Fukuoka (JP); Chihaya ADACHI, Fukuoka-shi, Fukuoka (JP); Anthony D'ALEO, Fukuoka-shi, Fukuoka (JP); Takashi FUJIHARA, Sawara-ku, Fukuoka-shi, Fukuoka (JP)

(21) Appl. No.: 17/438,108

(22) PCT Filed: Mar. 11, 2020
(86) PCT No.: PCT/JP2020/012809

§ 371 Date: Sep. 10, 2021

(30) Foreign Application Priority Data
Mar. 14, 2019 (JP) 2019-047762

(51) Int. Cl. H01S 5/12; H01S 5/36

(52) U.S. Cl. CPC H01S 5/1218; H01S 5/36

(57) ABSTRACT

Disclosed is an electrically driven organic semiconductor laser diode comprising a pair of electrodes, an optical resonator structure having a distributed feedback (DFB) structure, and one or more organic layers including a light amplification layer composed of an organic semiconductor, in which the distributed feedback structure is composed of a first-order Bragg scattering region, a two-dimensional distributed feedback, or a circular distributed feedback.

### TECHNICAL FIELD

The present invention relates to an electrically driven organic semiconductor laser diode and a method for producing it.

### BACKGROUND ART

The properties of optically pumped organic semiconductor lasers (OSLs) have dramatically improved in the last two decades as a result of major advances in both the development of high-gain organic semiconductor materials and the design of high-quality-factor resonator structures. The advantages of organic semiconductors as gain media for lasers include their high photoluminescence (PL) quantum yields, large stimulated emission cross sections, and broad emission spectra across the visible region along with their chemical tunability and ease of processing. Owing to recent advances in low-threshold distributed feedback (DFB) OSLs, optical pumping by electrically driven nanosecond-pulsed inorganic light-emitting diodes was demonstrated, providing a route toward a new compact and low-cost visible laser technology. However, the ultimate goal is electrically driven organic semiconductor laser diodes (OSLDs). In addition to enabling the full integration of organic photonic and optoelectronic circuits, the realization of OSLDs will open novel applications in spectroscopy, displays, medical devices (such as retina displays, sensors, and photodynamic therapy devices), and LIFI telecommunications.

The problems that have prevented the realization of lasing by the direct electrical pumping of organic semiconductors are mainly due to the optical losses from the electrical contacts and the triplet and polaron losses taking place at high current densities (see for example Non-Patent Literature 1). Approaches that have been proposed to solve these fundamental loss issues include the use of triplet quenchers to suppress triplet absorption losses and singlet quenching by singlet-triplet exciton annihilation as well as the reduction of the device active area (see for example Non-Patent Literature 2) to spatially separate where exciton formation and exciton radiative decay occur and minimize the polaron quenching processes. Recently, we could demonstrate the first electrically-pumped organic laser diode based on a mixed order distributed feedback (DFB) resonator structure (see Non-Patent Literature 3). But further improvement of the efficiency and stability of the organic laser diode is required.

### CITATION LIST

### Non-Patent Literatures

Non-Patent Literature 1: Samuel, I. D. W., Namdas, E. B. & Turnbull, G. A. How to recognize lasing. Nature Photon. 3, 546-549 (2009).
Non-Patent Literature 2: Hayashi, K. et al. Suppression of roll-off characteristics of organic light-emitting diodes by narrowing current injection/transport area to 50 nm. Appl. Phys. Lett. 106, 093301 (2015).
Non-Patent Literature 3: Sandanayaka, A. S. D. et al. Toward continuous-wave operation of organic semiconductor lasers. Science Adv. 3, e1602570 (2017).

### SUMMARY OF INVENTION

An object of the present invention is to provide a new electrically driven OSLD. As a result of assiduous studies, the present inventors have found that the object can be attained by the present invention. The present invention includes the following embodiments:

[1] An electrically driven organic semiconductor laser diode comprising a pair of electrodes, an optical resonator structure having a distributed feedback (DFB) structure, and one or more organic layers including a light amplification layer composed of an organic semiconductor, which satisfies one of the following conditions (i) to (iii):

(i) the distributed feedback structure is composed of a first-order Bragg scattering region,
(ii) the distributed feedback structure is composed of a two-dimensional distributed feedback, and
(iii) the distributed feedback structure is composed of a circular distributed feedback.

[2] The electrically driven organic semiconductor laser diode according to [1], which satisfies Condition (i).

[3] The electrically driven organic semiconductor laser diode according to [2], which is an edge-emission type.

[4] The electrically driven organic semiconductor laser diode according to [3], wherein the emission edge is an edge of a glass waveguide having a waveguide length of 50 μm or more.

[5] The electrically driven organic semiconductor laser diode according to [3] or [4], wherein the emission edge is coated with a transparent resin having a thickness in the optical radiation direction of 50 μm or more.

[6] The electrically driven organic semiconductor laser diode according to [1], which satisfies Condition (ii).

[7] The electrically driven organic semiconductor laser diode according to [1], which satisfies Condition (iii).

[8] The electrically driven organic semiconductor laser diode according to [7], wherein the distributed feedback structure has a lattice structure.

[9] The electrically driven organic semiconductor laser diode according to any one of [6] to [8], wherein the distributed feedback structure has a mixed structure of DFB grating structures differing in point of the order relative to laser emission wavelength.

[10] The electrically driven organic semiconductor laser diode according to [9], wherein the mixed structure is composed of a first-order Bragg scattering region and a second-order Bragg scattering region

[11] The electrically driven organic semiconductor laser diode according to [10], wherein the second-order Bragg scattering region is surrounded by the first-order Bragg scattering region.

[12] The electrically driven organic semiconductor laser diode according to [10], wherein the first-order Bragg scattering region and the second-order Bragg scattering region are formed alternately.

[13] The electrically driven organic semiconductor laser diode according to [1], which satisfies Conditions (ii) and (iii).

[14] The electrically driven organic semiconductor laser diode according to any one of [1] to [13], wherein the organic semiconductor contained in the light amplification layer is amorphous.

[15] The electrically driven organic semiconductor laser diode according to any one of [1] to [14], wherein the molecular weight of the organic semiconductor contained in the light amplification layer is 1000 or less.

[16] The electrically driven organic semiconductor laser diode according to any one of [1] to [15], wherein the organic semiconductor contained in the light amplification layer is a non-polymer.

[17] The electrically driven organic semiconductor laser diode according to any one of [1] to [16], wherein the organic semiconductor contained in the light amplification layer has at least one stilbene unit.

[18] The electrically driven organic semiconductor laser diode according to any one of [1] to [17], wherein the organic semiconductor contained in the light amplification layer has at least one carbazole unit.

[19] The electrically driven organic semiconductor laser diode according to any one of [1] to [18], wherein the organic semiconductor contained in the light amplification layer is 4,4′-bis[(N-carbazole)styryl]biphenyl (BSBCz).

[20] The electrically driven organic semiconductor laser diode according to any one of [1] to [19], which has an electron injection layer as one of the organic layers.

[21] The electrically driven organic semiconductor laser diode according to [20], wherein the electron injection layer contains Cs.

[22] The electrically driven organic semiconductor laser diode according to any one of [1] to [21], which has a hole injection layer as an inorganic layer.

[23] The electrically driven organic semiconductor laser diode according to [22], wherein the hole injection layer contains molybdenum oxide.

[24] The electrically driven organic semiconductor laser diode according to any one of [1] to [23], wherein the concentration of the organic semiconductor contained in the light amplification layer is 3% by weight or less.

[25] A method for producing electrically driven OSLD chips, comprising:

forming two or more electrically driven OSLD chip laminates each containing a pair of electrodes and plural layers sandwiched between the electrodes on a substrate, as spaced from each other thereon, and

cutting the substrate via the space between the laminates to give electrically driven OSLD chips each composed of the laminate and the substrate.

[26] The method according to [25], wherein the electrically driven OSLD chips each have a distributed feedback structure composed of a first-order Bragg scattering region.

[27] The method according to [25] or [26], wherein the electrically driven OSLD chips are edge-emission type ones.

[28] The method according to [27], wherein the emission edge is an edge of a glass waveguide having a waveguide length of 50 μm or more.

[29] The method according to any one of [25] to [28], wherein after the cutting, at least a part of the electrically driven OSLD chip is coated with a resin.

[30] The method according to [29], wherein the resin is a transparent fluororesin.

### BRIEF DESCRIPTION OF DRAWINGS

FIG. 1. Top view and side view of patterned ITO.

FIG. 2. Top view and side view of the product after sputtering SiO₂ on the patterned ITO.

FIG. 3. Top view and side view of the product after forming DFB.

FIG. 4. SEM image of 1st order DFB.

FIG. 5. Top view to show cut line and encapsulation.

FIG. 6. (A) Structure of device, and (B) side view of device configuration of laser detection.

FIG. 7. (A) Electroluminescent spectra of DFB laser diode under pulsed operation, (B) current density versus voltage, (C) EL intensity versus voltage, and (D) EL intensity versus current density.

FIG. 8. Optical simulation of 1^{st} order DFB, (A) mode at 480 nm (Q=832) S and (B) mode at 464 nm (Q=573).

FIG. 9. Electrical simulation of 1^{st} order DFB, (A) Current-Voltage characteristics, (B) singlet exciton density, (C) optical mode and (D) Significant spatial overlap.

FIG. 10. (A) SEM image of 2nd order square lattice-DFB, (B) SEM image of 2nd order 2D-DFB, and (C) schematic representation of organic semiconductor laser diode.

FIG. 11. (A, B) Emission spectra under optical pumping and (C, D) photonic stop band for waveguide mode.

FIG. 12. (A, B) Emission intensity versus excitation intensity under optical pumping.

FIG. 13. (A, B) Polarization dependence of the laser emission spectra, and (C, D) emission intensity as a function of polarization angle under optical pumping.

FIG. 14. Near and far-field beam images under optical pumping for square lattice-DFB.

FIG. 15. (A) Near-field and (B) far-field beam cross-sections of under optical excitation below threshold (a), near threshold (b), and above threshold (c) for square lattice-DFB.

FIG. 16. Near and far-field beam images under optical pumping for 2D-DFB.

FIG. 17. (A) Near-field and (B) far-field beam cross-sections of under optical excitation below threshold (a), near threshold (b), and above threshold (c) for 2D-DFB.

FIG. 18. Schematic representation of organic semiconductor laser diode.

FIG. 19. Current density-voltage (J-V) curves for devices and external quantum efficiency versus current density in the OLED.

FIG. 20. Schematic representation of EOD and HOD.

FIG. 21. Current density-voltage (J-V) curves for EOD and HOD devices.

FIG. 22. SEM images of second order square lattice DFB and second order 2D-DFB.

FIG. 23. Current density-voltage (J-V) curves for devices and external quantum efficiency versus current density for the DFB grating OLED. The device structure is shown in FIG. 10(c).

FIG. 24. Laser spectra with changing voltage.

FIG. 25. Optical simulation of 2^{nd} order 2D grating (A) Schematic representation of 2^{nd} order 2D grating (B) Resonant optical mode at 481 nm (Q=9071) and (C) top view of resonant mode.

FIG. 26. (A, B) SEM images of circular-DFB.

FIG. 27. (A, B) Emission spectra under optical pumping and (C, D) photonic stop band for waveguide mode.

FIG. 28. (A, B) Emission intensity versus excitation intensity under optical pumping.

FIG. 29. (A, B) Polarization dependence of the laser emission spectra and (C, D) emission intensity as a function of polarization angle under optical pumping.

FIG. 30. Near and far-field beam images under optical pumping for circular second order-DFB.

FIG. 31. (A) Near-field and (B) far-field beam cross-sections of under optical excitation below threshold (a), near threshold (b), and above threshold (c) for circular 2nd order-DFB.

FIG. 32. Near and far-field beam images under optical pumping for circular mixed order-DFB.

FIG. 33. (A) Near-field and (B) far-field beam cross-sections of under optical excitation below threshold (a), near threshold (b), and above threshold (c) for circular mixed order-DFB.

FIG. 34. Laser microscope images of a circular mixed-order DFB grating structure prepared using SiO₂ on ITO pattern substrate.

FIG. 35. Microscope images of and organic circular DFB laser with and without driving. Current density-voltage (J-V) curves for devices with and without circular DFB. External quantum efficiency versus current density in the OLED with and without DFB.

FIG. 36. SEM images for low threshold DFB grating structure: (A) second order square lattice-DFB, (B) mixed order square lattice-DFB, (C) second order 2D-DFB, (D) mixed order 2D-DFB, (E) second order circle lattice-DFB, (F) mixed order circle lattice-DFB, and (G) second order circle 2D-DFB. Scale size: (A) 3 nm, (B) 40 nm, (C) 5 nm, (D) 10 50 nm, (E) 20 nm and (F) 5 nm.

FIG. 37. Structure of the near infrared mixed-order DFB OSLD

FIG. 38. J-V curve of the NIR OSLD

FIG. 39. Emission spectra of the NIR OSLD as a function of the injected current density, and pictures showing the device operating at various applied voltages as well as the output laser beam.

FIG. 40. Output EL intensity as a function of the current density and as a function of the applied voltage.

### DETAILED DESCRIPTION OF INVENTION

The contents of the invention will be described in detail below. The constitutional elements may be described below with reference to representative embodiments and specific examples of the invention, but the invention is not limited to the embodiments and the examples. In the present specification, a numerical range expressed by “from X to Y” means a range including the numerals X and Y as the lower limit and the upper limit, respectively.

The electrically driven OSLD of the present invention contains at least a pair of electrodes, an optical resonator structure having a distributed feedback structure and one or more organic layers containing a light amplification layer composed of an organic semiconductor. The electrically driven OSLD of the present invention satisfies one of the following conditions (i) to (iii):

(i) the distributed feedback structure is composed of a first-order Bragg scattering region,
(ii) the distributed feedback structure is composed of a two-dimensional distributed feedback, and
(iii) the distributed feedback structure is composed of a circular distributed feedback.

The constitution and the characteristics of the present invention are described in detail herein under.

### (Optical Resonator Structure)

In the electrically driven OSLD of the present invention, the optical resonator structure may be formed preferably on an electrode. The optical resonator structure has a distributed feedback structure.

In the case of satisfying (i), preferably, an area of 90% or more of the DFB structure (distributed feedback structure) is composed of a first-order Bragg scattering region, and the proportion may be 95% or more, or may be 99% or more, and is more preferably 100%. Specific examples of the first-order Bragg scattering region are shown in FIG. 3. Also in the case of satisfying (i), preferably, the electrically driven OSLD is an edge-emission type. Of the edge-emission type, the emission edge is preferably an edge of a glass waveguide. Of the glass waveguide, the waveguide length from the edge is preferably 10 μm or more, and may be selected from a range of 50 μm or more, or 80 μm or more, or may be selected from a range of 500 μm or less, or 200 μm or less. The emission face may be coated with a transparent resin (preferably a transparent fluororesin), and in the case of an edge-emission type, the resin thickness in the optical radiation direction may be, for example, within a range of 100 μm or more, or 300 μm or more, or may be within a range of 1000 μm or less, or 500 μm or less.

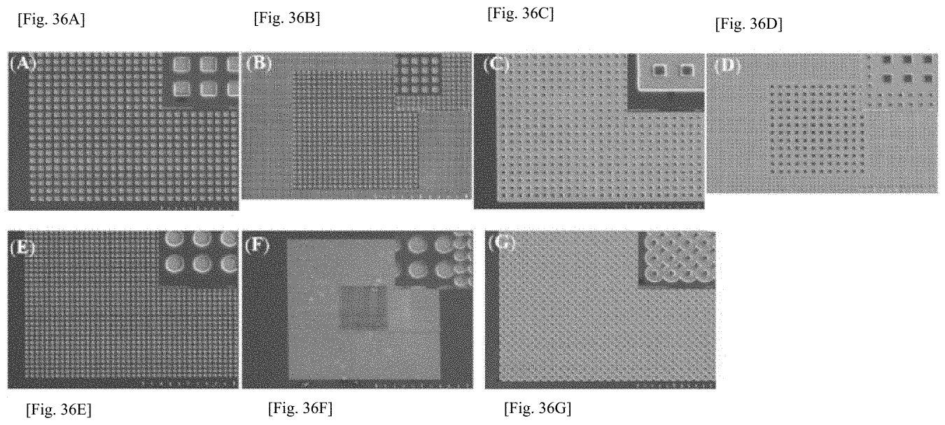

In the case of satisfying (ii), the DFB structure is a two dimensional resonator structure. Specific examples of the electrically driven OSLD satisfying (ii) include those shown in FIGS. 36 (C), (D) and (G). The DFB structure of the electrically driven OSLD satisfying (ii) may be composed of a DFB grating structure alone having the same order relative to emission wavelength, or may have a mixture of DFB grating structures differing in point of the order relative to emission wavelength. An example of the former case is a structure composed of a second-order Bragg scattering region alone. Examples of the latter case include an optical resonator structure composed of the second-order Bragg scattering region surrounded by the first-order Bragg scattering region and a structure where the second-order Bragg scattering region and the first-order scattering region are formed alternately. Examples of the electrically driven OSLD satisfying (ii) include a circular resonator structure and a whispering gallery type optical resonator structure.

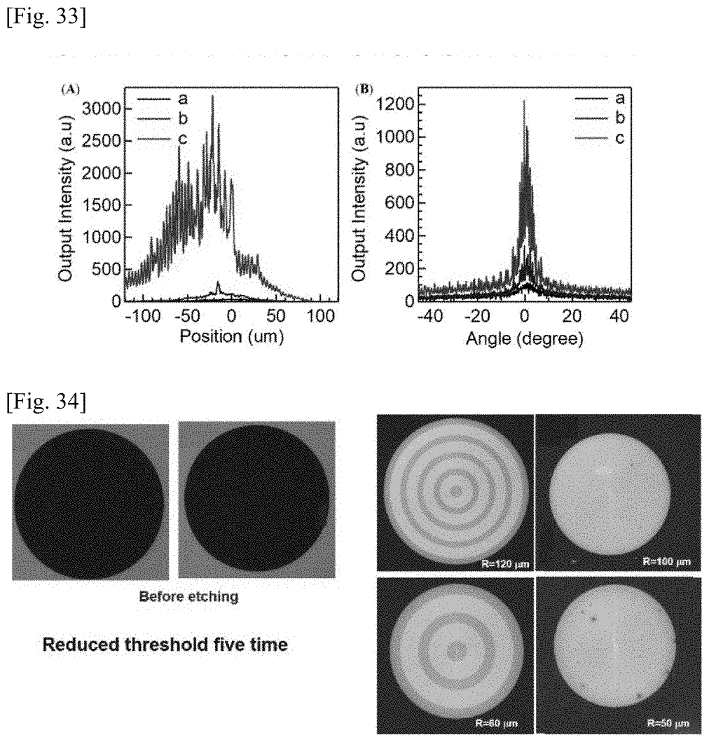

In the case of satisfying (iii), at least a part of the DFB structure contains a circular resonator structure. Typical examples of the circular resonator structure include concentric pattern structures shown in FIGS. 26 and 34. Preferably, the circulator resonator structure occupies an area of 50% or more of the DFB structure contained in the electrically driven OSLD, and may occupy 90% or more, or 99% or more, or even 100%. Specific examples of the electrically driven OSLD include those shown in FIGS. 36 (E), (F) and (G). In the case of satisfying (iii), the DFB structure may be composed of a DFB grating structure alone having the same order relative to emission wavelength, or may have a mixture of DFB grating structures differing in point of the order relative to emission wavelength. A preferred example of the latter is an optical resonator structure composed of the second-order Bragg scattering region surrounded by the first-order Bragg scattering region, as shown in FIG. 36(F), but the structure employable in the present invention is not limited to this embodiment. Also in the case of satisfying (iii), the DFB structure may be a lattice-like one as in FIGS. 36 (E) and (F), or may be a two-dimensional one as in FIG. 36 (G). The electrically driven OSLD satisfying (iii) is excellent in that it can reduce the lasing threshold.

The material to constitute the optical resonator structure includes an insulating material such as SiO₂, etc. The depth of the grating is preferably 75 nm or less, and is more preferably selected from a range of 10 to 75 nm. The depth may be, for example, 40 nm or more, or may be less than 40 nm.

### (Light Amplification Layer)

The light amplification layer to constitute the electrically driven OSLD of the present invention includes an organic semiconductor compound containing a carbon atom but not containing a metal atom. Preferably, the organic semiconductor compound is composed of one or more atoms selected from the group consisting of a carbon atom, a hydrogen atom, a nitrogen atom, an oxygen atom, a sulfur atom, a phosphorous atom, and a boron atom. For example, there may be mentioned an organic semiconductor compound composed of a carbon atom, a hydrogen atom and a nitrogen atom. A preferred example of the organic semiconductor compound is a compound having at least one of a stilbene unit and a carbazole unit, and a more preferred example of the organic semiconductor compound is a compound having both of a stilbene unit and a carbazole unit. The stilbene unit and the carbazole unit may be substituted with a substituent such as an alkyl group or the like, or may be unsubstituted. Preferably, the organic semiconductor compound is a non-polymer not having a repeating unit. Preferably, the molecular weight of the compound is 1000 or less, for example, it may be 750 or less. The light amplification layer may contain 2 or more kinds of organic semiconductor compounds, but preferably contains only one kind of an organic semiconductor compound.

The organic semiconductor compound for use in the present invention may be selected from laser gain organic semiconductor compounds that enable laser oscillation when used in an organic light emitting layer of a photoexcitation organic semiconductor laser. One of the most preferable organic semiconductor compound is 4,4′-bis[(N-carbazole)styryl]biphenyl (BSBCz) because of its excellent combination of optical and electrical properties such as a low amplified spontaneous emission (ASE) threshold in thin films (0.30 μJ cm⁻² under 800-ps pulse photoexcitation according to Aimono, T. et al. Appl. Phys. Lett. 86, 71110 (2005)) and the ability to withstand the injection of current densities as high as 2.8 kA cm⁻² under 5-μs pulse operation in OLEDs with maximum electroluminescence (EL) external quantum efficiencies (η_{EQE}) of over 2% (see Hayashi, K. et al. Appl. Phys. Lett. 106, 093301 (2015)). Furthermore, lasing at a high repetition rate of 80 MHz and under long pulse photoexcitation of 30 ms were recently demonstrated in optically pumped BSBCz-based DFB lasers and were largely possible because of the extremely small triplet absorption losses at the lasing wavelength of BSBCz films. Apart from BSBCz, also employable are, for example, compounds having an ASE threshold of preferably 0.60 μJ cm⁻² or less, more preferably 0.50 μJ cm⁻² or less, even more preferably 0.40 μJ cm⁻² or less, when formed into the same thin film as in Appl. Phys. Lett. 86, 71110 (2005). and measured under the 800-ps pulse photoexcitation condition. In addition, compounds are employable, which exhibit durability of preferably 1.5 kA cm⁻² or more, more preferably 2.0 kA cm⁻² or more, even more preferably 2.5 kA cm⁻² or more, when formed into the same device as in Appl. Phys. Lett. 106, 093301 (2015) and measured under the 5-μs pulse operation condition.

The thickness of the light amplification layer to constitute the electrically driven OSLD of the present invention is preferably 80 to 350 nm, more preferably 100 to 300 nm, even more preferably 150 to 250 nm.

The concentration of an organic semiconductor compound in the light amplification layer may be for example within the range of less than 10 wt. %, within the range of 5 wt. % or less, within the range of 3 wt. % or less, or within the range of 1 wt. % or less.

### (Other Layers)

The electrically driven OSLD of the present invention may have an electron injection layer, a hole injection layer and others in addition to the light amplification layer. These may be organic layers or inorganic layers free from organic materials. In the case where the electrically driven OSLD has two or more organic layers, it preferably has a laminate structure of organic layers alone not having any non-organic layer therebetween. In this case, the two or more organic layers may contain the same organic compound as in the light amplification layer. The performance of the electrically driven OSLD tends to be better when the number of the heterointerfaces of the organic layers therein is smaller, and therefore, the number of the organic layers therein is preferably 6 or less, more preferably 3 or less. In the case where the electrically driven OSLD has 2 or more organic layers, preferably, the thickness of the light amplification layer is more than 50% of the total thickness of the organic layers, more preferably more than 60%, even more preferably more than 70%. When the electrically driven OSLD has 2 or more organic layers, the total thickness of the organic layers may be, for example, 100 nm or more, 120 nm or more, or 170 or more, and may be 370 nm or less, 320 nm or less, or 270 nm or less. Preferably, the refractive index of the electron injection layer and the hole injection layer is smaller than the refractive index of the light amplification layer.

In the case where an electron injection layer is provided, a substance facilitating electron injection into the light amplification layer is made to exist in the electron injection layer. In the case where a hole injection layer is provided, a substance facilitating hole injection into the light amplification layer is made to exist in the hole injection layer. These substances may be an organic compound or an inorganic substance. For example, the inorganic substance for the electron injection layer includes an alkali metal such as Cs, etc., and the concentration thereof in the electron injection layer containing an organic compound may be, for example, 1% by weight more, or 5% by weight or more, or 10% by weight or more, and may be 40% by weight or less, or 30% by weight or less. The thickness of the electron injection layer may be, for example, 3 nm or more, 10 nm or more, or 30 nm or more, and may be 100 nm or less, 80 nm or less, or 60 nm or less.

As one preferred embodiment of the present invention, an electrically driven OSLD provided with an electron injection layer and a light amplification layer as organic layers, and with a hole injection layer as an inorganic layer may be exemplified. The inorganic substance to constitute the hole injection layer includes a metal oxide such as molybdenum oxide, etc. The thickness of the hole injection layer may be, for example, 1 nm or more, 2 nm or more, or 3 nm or more, and may be 100 nm or less, 50 nm or less, or 20 nm or less.

### (Electrode)

The electrically driven OSLD of the present invention has a pair of electrodes. For light output, one electrode is preferably transparent. For the electrode, an electrode material generally used in the art may be appropriately selected in consideration of the work function thereof, etc. Preferred electrode materials include, though not limited thereto, Ag, Al, Au, Cu, ITO, etc.

(Preferred Electrically driven OSLD)

In the electrically driven OSLD of the present invention, preferably, the excitons generated by current excitation do not substantially undergo annihilation. The loss by the exciton annihilation is preferably less than 10%, more preferably less than 5%, further more preferably less than 1%, still further more preferably less than 0.1%, still further more preferably less than 0.01%, and most preferably 0%.

Also preferably, the electrically driven OSLD of the present invention shows no substantial polaron absorption loss at a lasing wavelength. In other words, preferably, there is no substantial overlap between the polaron absorption spectrum and the emission spectrum of the organic semiconductor laser. The loss by the polaron absorption is preferably less than 10%, more preferably less than 5%, further more preferably less than 1%, still further more preferably less than 0.1%, still further more preferably less than 0.01%, and most preferably 0%.

Preferably, the oscillation wavelength of the electrically driven OSLD of the present invention does not substantially overlap with the absorption wavelength region of an excited state, a radical cation, or a radical anion. Absorption in them may be caused by singlet-singlet, triplet-triplet, or polaron absorption. The loss by absorption in an excited state is preferably less than 10%, more preferably less than 5%, further more preferably less than 1%, still further more preferably less than 0.1%, still further more preferably less than 0.01%, and most preferably 0%.

Preferably, the electrically driven OSLD of the present invention is free from a triplet quencher.

### (Production Method for Electrically Driven OSLD)

The present invention also provides a production method for the electrically driven OSLD.

An OSLD including a pair of electrodes and plural layers sandwiched between the electrodes has heretofore been produced by cutting it out of a wafer. Specifically, a pair of electrodes and plural layers sandwiched between the electrodes are formed on a substrate to produce a wafer, and then individual OSLD chips are cut out of it. In cutting out individual OSLD chips, the optical resonator structure and the light amplification layer formed between the electrodes are also cut along with the substrate. Consequently, the cut faces of the layers are inevitably roughened. As a result of investigations, the present inventors have found that the roughened cut faces have some negative influences on laser oscillation characteristics. Accordingly, the present inventors have considered a production method where the layers formed between electrodes are not cut in cutting out individual OSLD chips. As a result, the present inventors have conceived an idea of not forming electrodes and layers of constituting an OSLD in the region of a substrate to be cut, and cutting the substrate alone, and have developed a method of producing OSLD chips free from the problem. Specifically, the production method of the present invention is a method for producing OSLD chips each composed of an OSLD chip laminate and a substrate, which includes forming two or more OSLD chip laminates each containing a pair of electrodes and plural layers sandwiched between the electrodes on a substrate, as spaced from each other thereon, and cutting the substrate via the space between the two or more OSLD chip laminates to give OSLD chips each composed of the OSLD chip laminate and the substrate. According to the production method, the layers constituting the OSLD chips need not to be cut in cutting out the individual OSLD chips, and therefore the cut faces can be prevented from being roughened.

The production method of the present invention is useful especially as a method for producing edge-emission type electrically driven OSLDs. The method is useful as a production method for electrically driven OSLDs each having an optical resonator structure mainly composed of a first-order Bragg scattering region, and is especially useful as a production method for electrically driven OSLDs each having the optical resonator structure composed of the first-order Bragg scattering region alone.

At least a part of the electrically driven OSLD cut out according to the production method of the present invention may be coated with a resin. For example, the electrodes formed on the substrate and all the layers sandwiched between the electrodes thereon may be coated with a resin. In the case where the emission face and the emission edge are coated with a resin, a transparent resin is used. One preferred resin is a transparent fluororesin such as CYTOP™. In the case where the emission face or the emission edge are coated with a resin, the resin thickness in the optical radiation direction may be, for example, within a range of 100 μm or more, or 300 μm or more, or may be within a range of 1000 μm or less, or 500 μm or less. The emission edge to be coated with a resin is preferably an edge of a glass waveguide having a length of 50 μm or more.

The electrically driven OSLD of the present invention mentioned above is preferably one produced according to the production method of the present invention. However, even those produced according any other method than the production method of the present invention are included in the scope of the electrically driven OSLD of the present invention so far as they satisfy the requirements stated in the claims of the present application.

### EXAMPLES

The characteristic features of the present invention will be described more specifically with reference to Examples given below. The materials, processes, procedures and the like shown below may be appropriately modified unless they deviate from the substance of the invention. Accordingly, the scope of the invention is not construed as being limited to the specific examples shown below.

### (Example 1) Electrically Driven Organic Semiconductor Laser Diodes with First Order Distributed Feedback DFB

### <Device Fabrication>

Indium tin oxide (ITO)-coated glass substrates (30-nm-thick ITO, Atsugi Micro Co.) were cleaned by ultrasonication using neutral detergent, pure water, acetone, and isopropanol followed by UV-ozone treatment. A 60-nm-thick layer of SiO₂, which would become the DFB grating, was sputtered at 100° C. onto the ITO-coated glass substrates. The argon pressure during the sputtering was 0.66 Pa. The RF power was set at 100 W. Substrates were again cleaned by ultrasonication using isopropanol followed by UV-ozone treatment. The SiO₂ surfaces were treated with hexamethyldisilazane (HMDS) by spin coating at 4,000 rpm for 15 seconds and annealed at 120° C. for 120 seconds. A resist layer with a thickness of around 70 nm was spin-coated on the substrates at 4,000 rpm for 30 seconds from a ZEP520A-7 solution (ZEON Co.) and baked at 180° C. for 240 seconds.

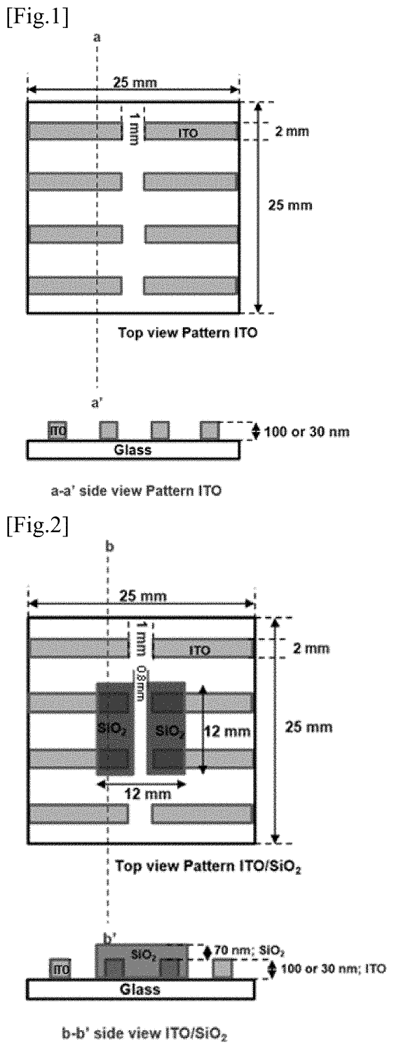

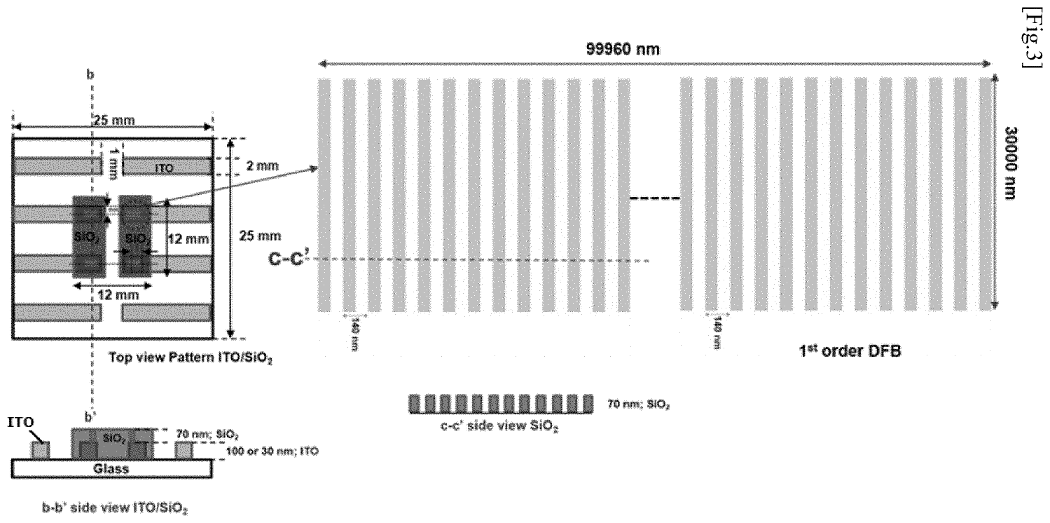

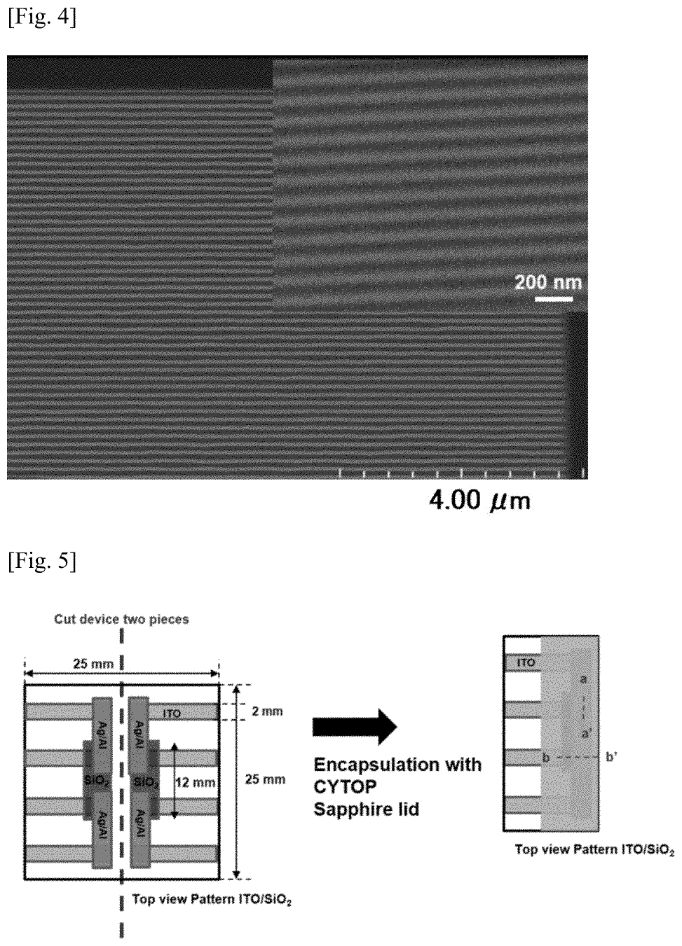

Electron beam lithography was performed to draw grating patterns on the resist layer using a JBX-5500SC system (JEOL) with an optimized dose of 0.1 nC/cm². After the electron beam irradiation, the patterns were developed in a developer solution (ZED-N50, ZEON Co.) at room temperature. The patterned resist layer was used as an etching mask while the substrate was plasma etched with CHF₃ using an EIS-200ERT etching system (ELIONIX). To completely remove the resist layer from the substrate, the substrate was plasma-etched with O₂ using a FA-1EA etching system (SAMCO). The etching conditions were optimized to completely remove the SiO₂ from the grooves in the DFB until the ITO was exposed (FIGS. 1-3). The gratings formed on the SiO₂ surfaces were observed with SEM (SU8000, Hitachi) (FIG. 4). EDX (at 6.0 kV, SU8000, Hitachi) analysis was performed to confirm complete removal of SiO₂ from ditches in the DFB.

The DFB substrates were cleaned by conventional ultrasonication. Organic layers and a metal electrode were then vacuum-deposited by thermal evaporation under a pressure of 1.5×10⁻⁴ Pa with a total evaporation rate of 0.1-0.2 nm/s on the substrates to fabricate OSLDs with the structure indium tin oxide (ITO) (30 nm)/20 wt % Cs:CBP (60 nm)/10 wt % BSBCz:CBP (150 nm)/MoO₃ (3 nm)/HATCN (10 nm)/Ag (100 nm). The SiO₂ layers on the ITO surface acted as insulators in addition to a DFB grating. Therefore, the current flow regions of the OLEDs were limited to the DFB regions where CBP is in direct contact with ITO. Reference OLEDs with an active area of 700×1400 μm were also prepared with same current flow region.

### <Device Characterization>

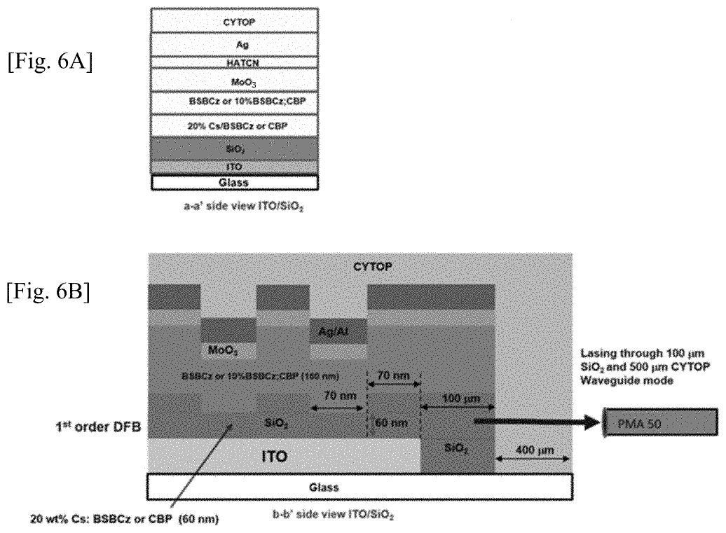

All the devices were cut center as shown in FIG. 5 to get fine edge in nitrogen-filled glove box to prevent any degradation resulting from moisture and oxygen. All device characterizations were performed under N₂. We also performed measurement with encapsulating using CYTOP™ as shown in FIG. 6. Current density-voltage-ηEQE (J-V-ηEQE) characteristics (DC) of the OSLDs and OLEDs were measured using an integrating sphere system (A10094, Hamamatsu Photonics) at room temperature. For pulse measurements, rectangular pulses with a pulse width of 400 ns, pulse period of 1 ms, repetition frequency of 1 kHz, and varying peak currents were applied to the devices at ambient temperature using a pulse generator (NF, WF1945). Using these conditions, we could apply to a properly working OSLD from a good batch roughly 50 pulse at 1 kA/cm² (above threshold. Devices were fabricated in this work with a yield of about 50%. The J-V-luminance characteristics under pulse driving were measured with an amplifier (NF, HSA4101) and a photomultiplier tube (PMT) (C9525-02, Hamamatsu Photonics). Both the PMT response and the driving square wave signal were monitored on a multi-channel oscilloscope (Agilent Technologies, MSO6104A). The ηEQE was calculated by dividing the number of photons, which was calculated from the PMT-response EL intensity with a correction factor, by the number of injected electrons, which was calculated from the current. Output power was measured using a laser power meter (OPHIR Optronics Solution Ltd., StarLite 7Z01565).

To measure the spectra, emitted laser light for both optically and electrically pumped OSLDs was collected from edge of the device with an optical fiber connected to a multichannel spectrometer (PMA-50, Hamamatsu Photonics) and placed 3 cm away from the device. The beam profile of the OSLDs was checked by using a CCD camera (beam profiler WimCamD-LCM, DataRay). For characteristics of OSLDs and OSL under optical pumping, pulsed excitation light from a nitrogen-gas laser (NL100, N₂ laser, Stanford Research System) was focused in a 6×10⁻³ cm² area of the device through a lens and slit. The excitation wavelength was 337 nm, pulse width was 3 ns, and repetition rate was 20 Hz.

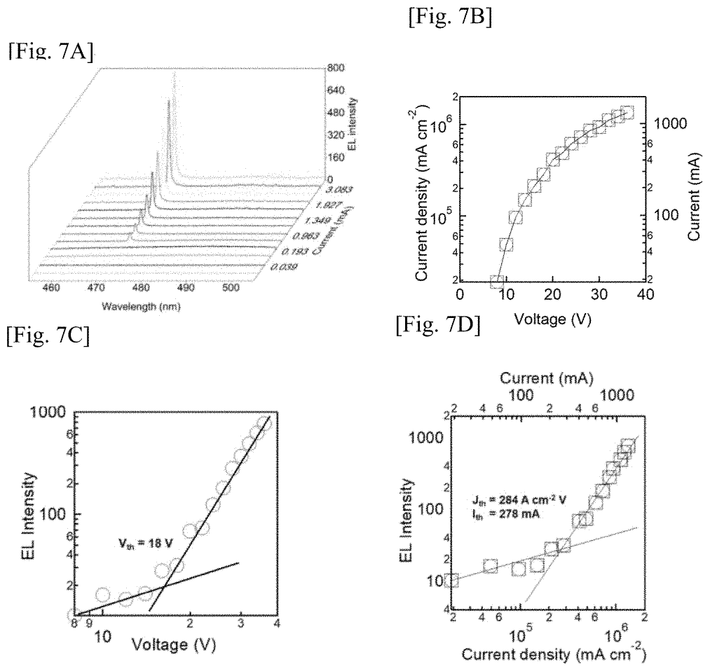

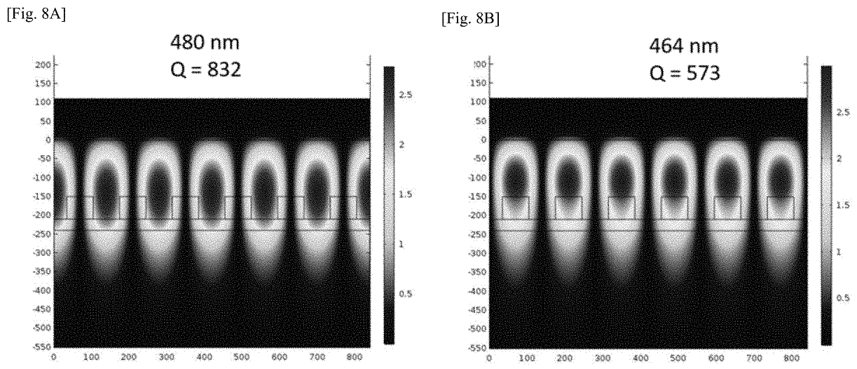

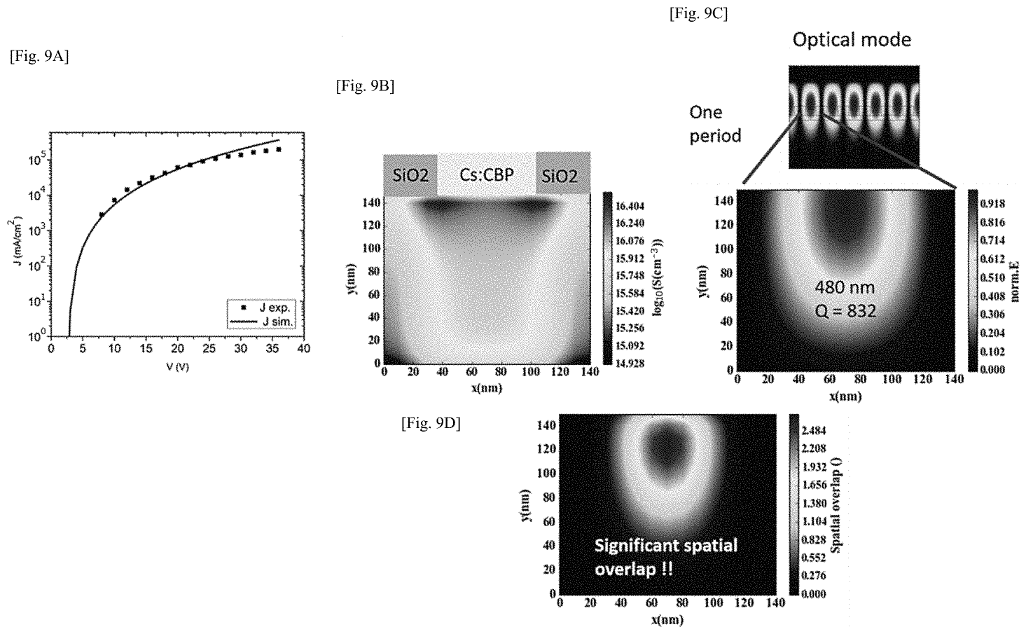

The measurement results were shown in FIG. 7(A)-(D). FIG. 7(A) shows current density versus voltage, FIG. 7(B) shows electroluminescent spectra under pulsed operation, FIG. 7(C) shows EL intensity versus voltage, and FIG. 7(D) shows EL intensity versus current density. FIGS. 8 and 9 show optical and electrical simulation of 1^{st} order grating.

### (Example 2) Electrically Driven Organic Semiconductor Laser Diodes with Two-Dimensional Distributed Feedback

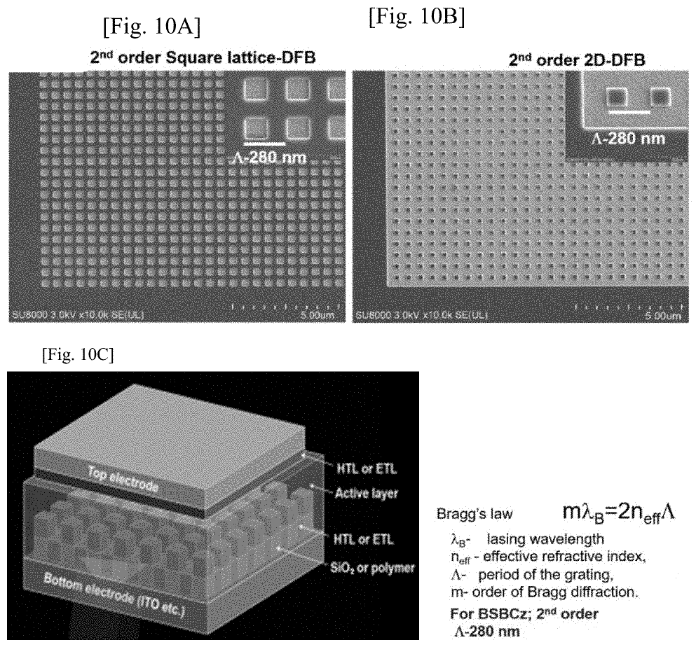

Electrically driven organic semiconductor laser diodes were manufactured in the same manner as Example 1, except that the DFB structure was changed as shown in FIG. 10(A) or (B). The manufactured laser diodes have the structure shown in FIGS. 10(C) and 16.

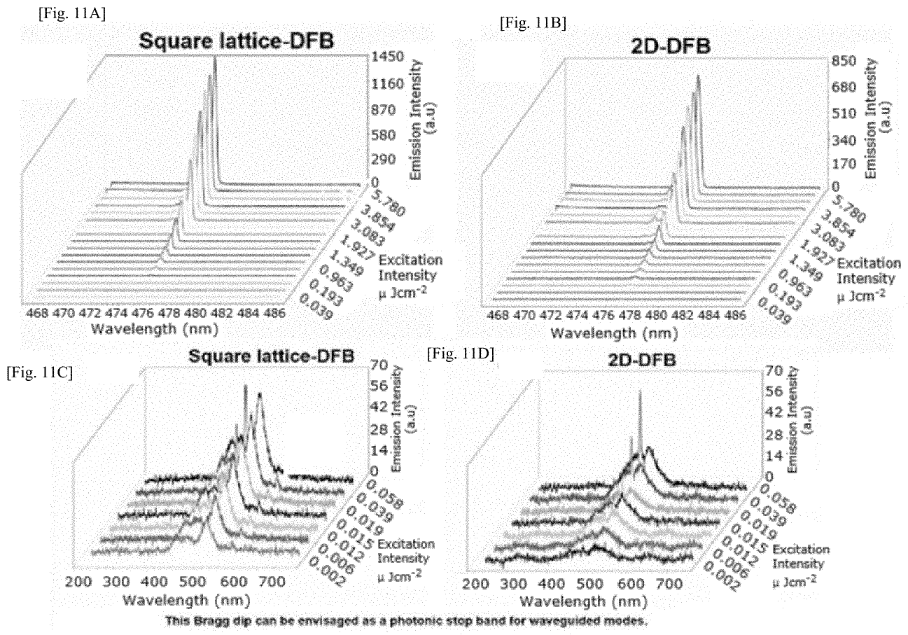

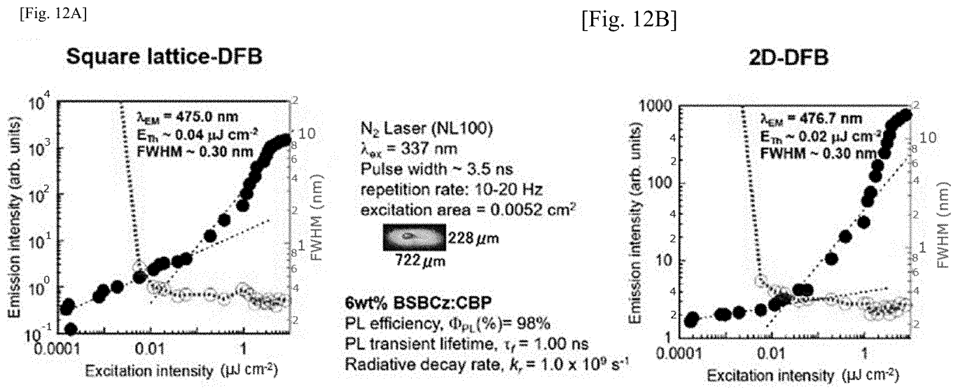

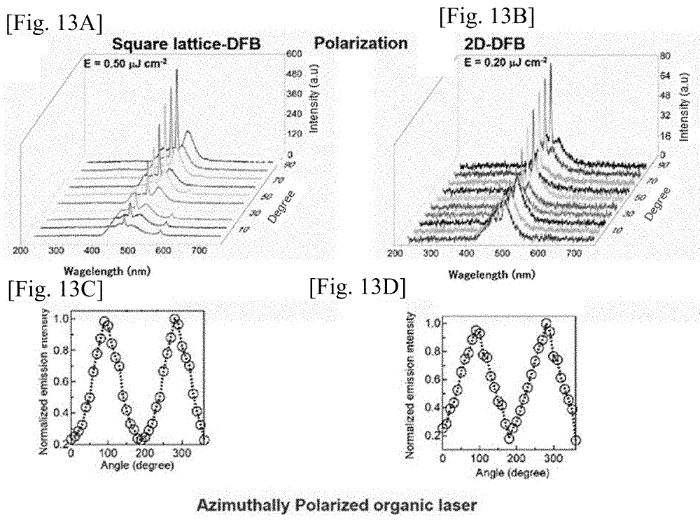

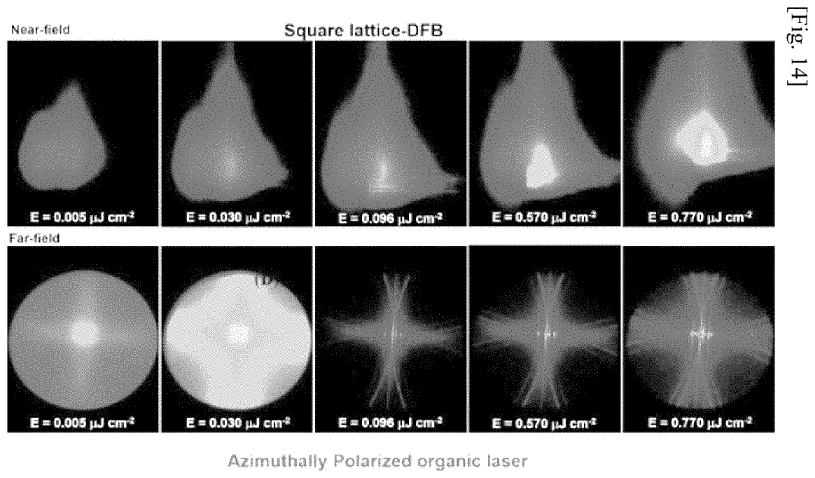

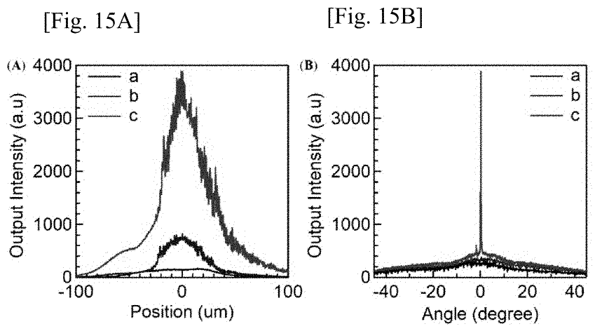

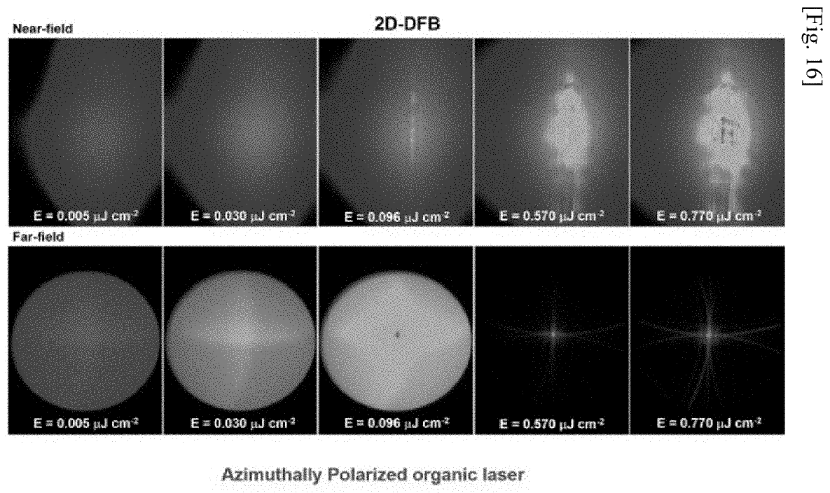

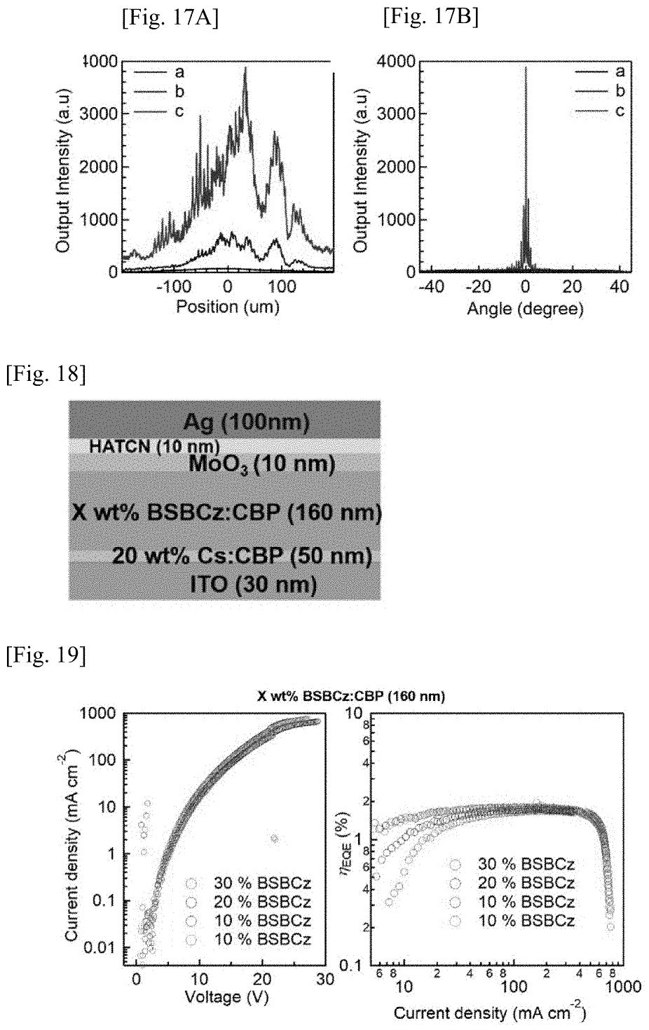

The measurement results under optical pumping are shown in FIGS. 11-13. The excitation light was incident upon the devices at edge. Excitation intensities were controlled using a set of neutral density filters. Steady-state PL spectroscopy was monitored using a spectrofluorometer (FP-6500, JASCO) and a spectrometer (PMA-50) in FIG. 11-13. Near-field patterns of an OSL, an OSLD and an OSLD were taken using a laser beam profiler (C9164-01, Hamamatsu Photonics), and far-field patterns of an OSL were taken using laser beam profiler (C9664-01G02, Hamamatsu Photonics) (FIGS. 14-17).

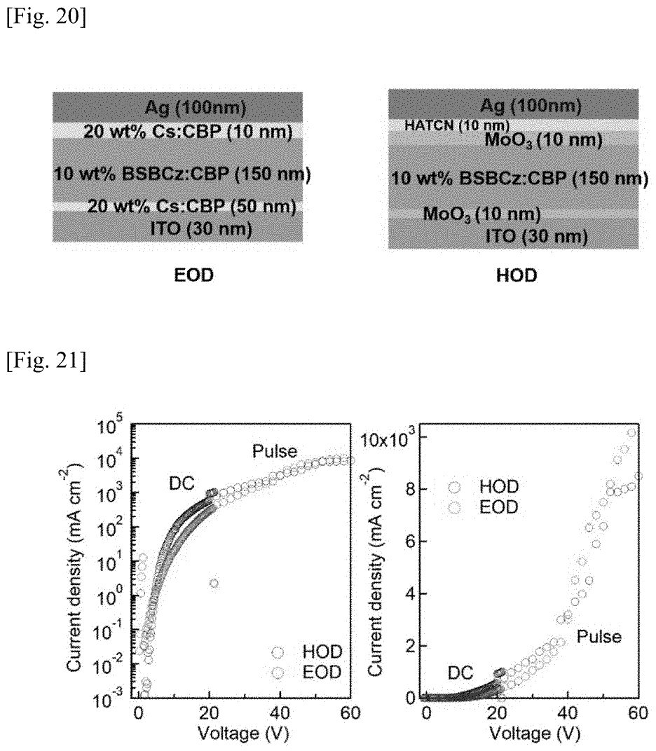

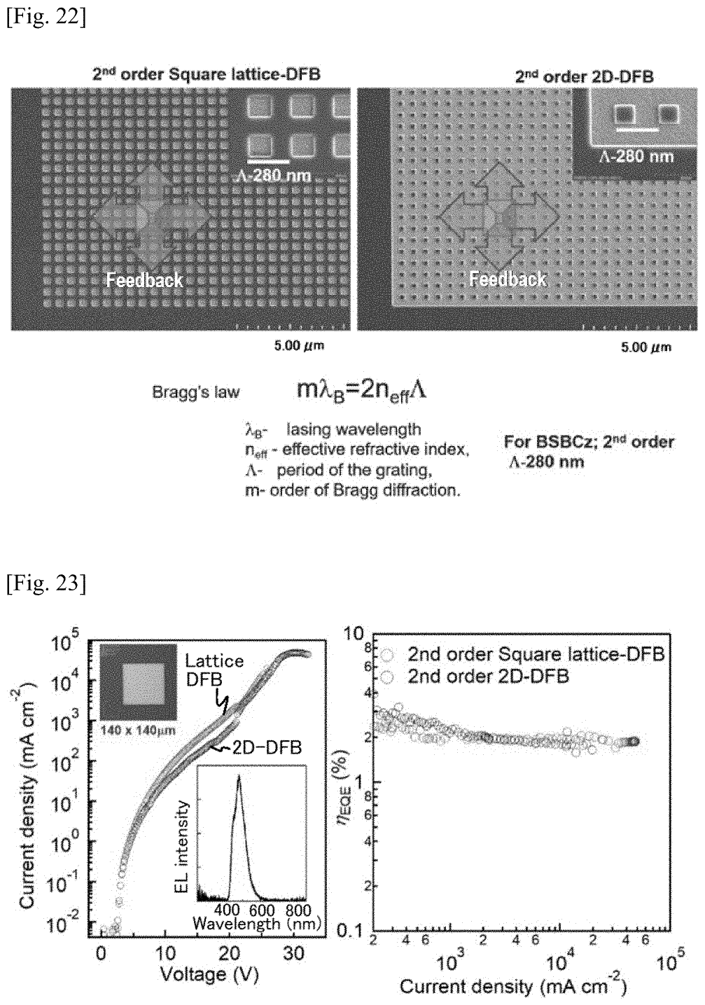

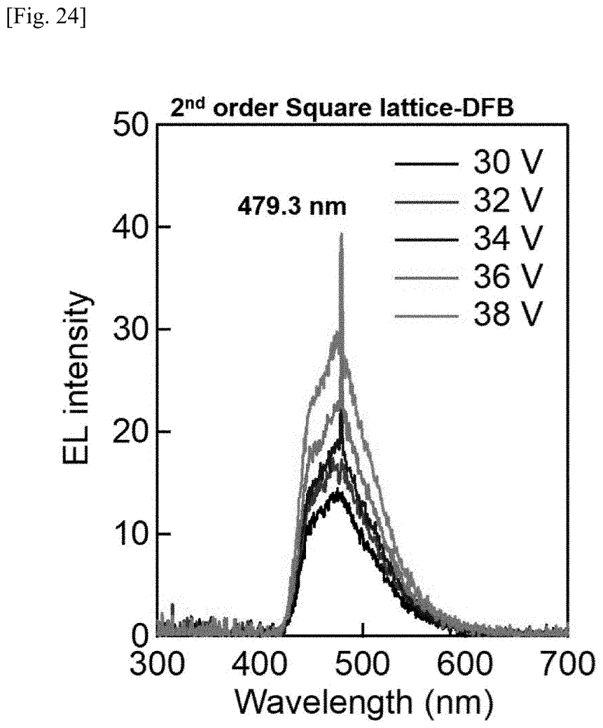

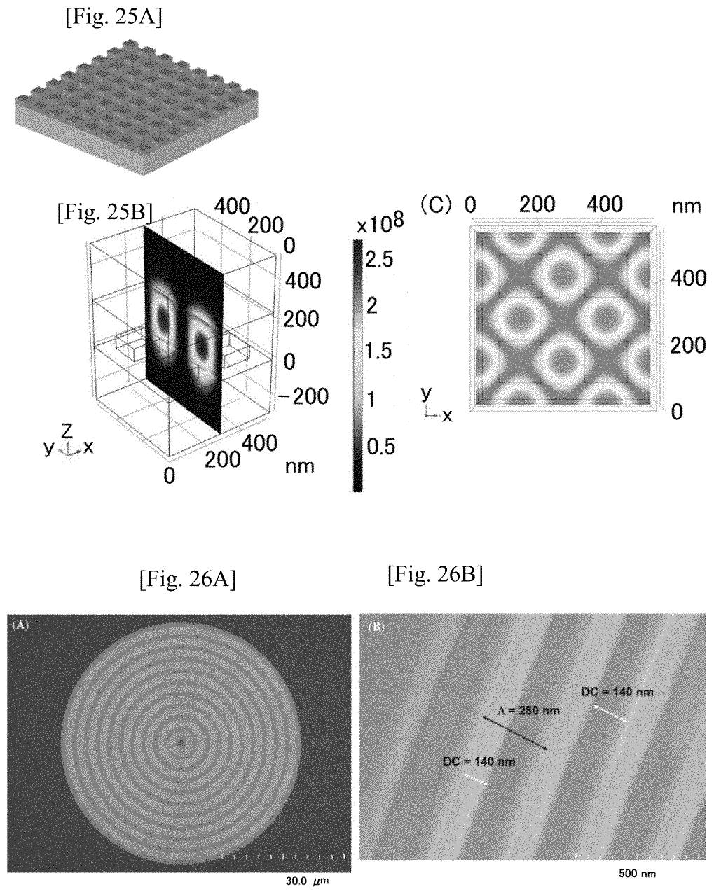

The measurement results of the electrically driven organic semiconductor laser diodes are shown in FIGS. 20-24. FIG. 19 shows current density-voltage (J-V) curves, FIG. 20 shows the structures of EOD and HOD devices, FIG. 21 shows current density-voltage (J-V) curves for the EOD and HOD devices, FIG. 22 shows SEM images of DFB's, FIG. 23 shows current density-voltage (J-V) curves and external quantum efficiency versus current density for the DFB grating OLED, and FIG. 24 shows laser spectra with changing voltage. FIG. 25 shows simulation of 2^{nd} order 2D grating.

### (Example 3) Electrically Driven Organic Semiconductor Laser Diodes with Circular Distributed Feedback

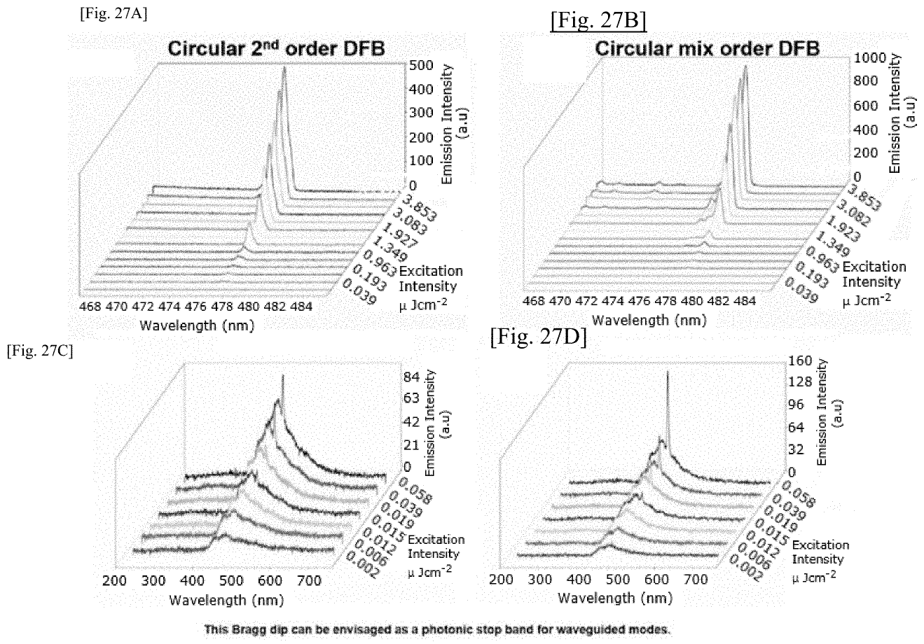

Electrically driven organic semiconductor laser diodes were manufactured in the same manner as Example 1, except that the DFB structure was changed as shown in FIGS. 26 and 34. The excitation light was incident upon the devices at edge. Excitation intensities were controlled using a set of neutral density filters. Steady-state PL spectroscopy was monitored using a spectrofluorometer (FP-6500, JASCO) and a spectrometer (PMA-50) in FIG. 27-29. Near-field patterns of an OSL, an OSLD and an OSLD were taken using a laser beam profiler (C9164-01, Hamamatsu Photonics), and far-field patterns of an OSL were taken using laser beam profiler (C9664-01G02, Hamamatsu Photonics) (FIGS. 30-33).

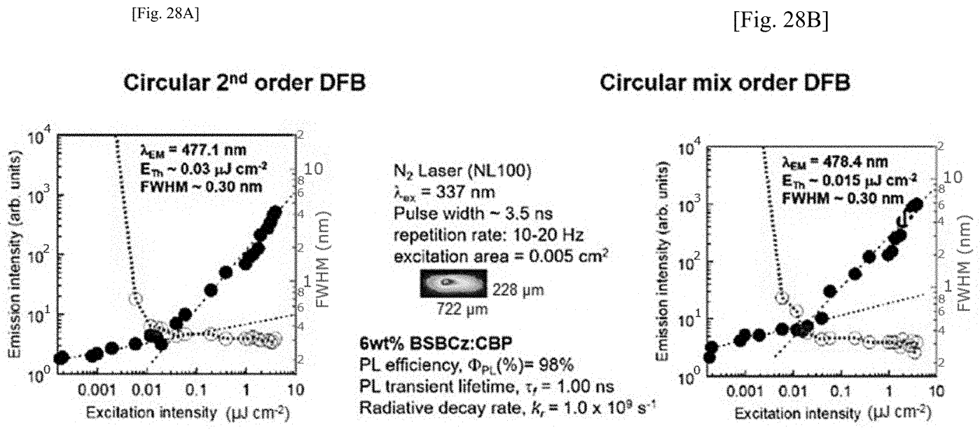

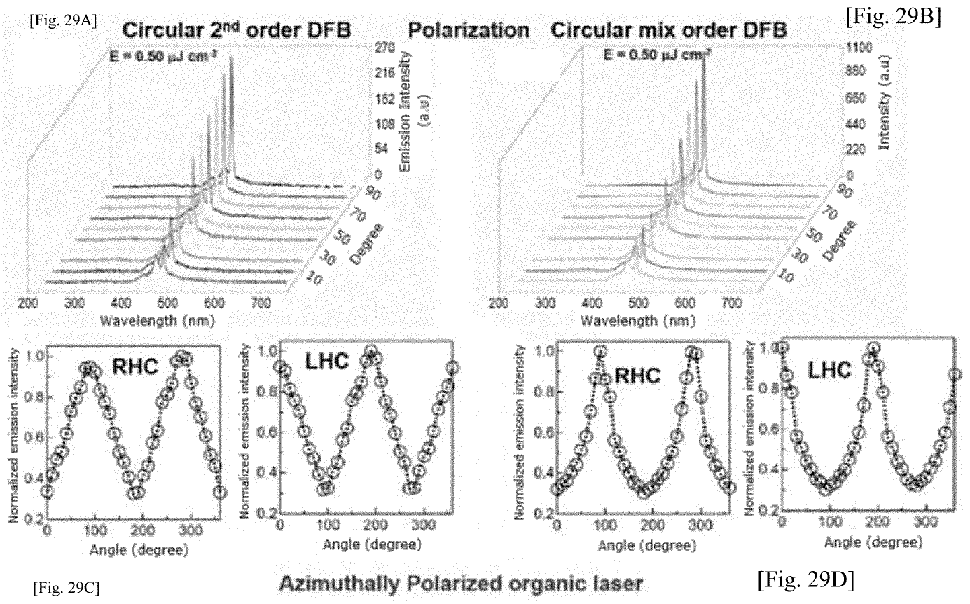

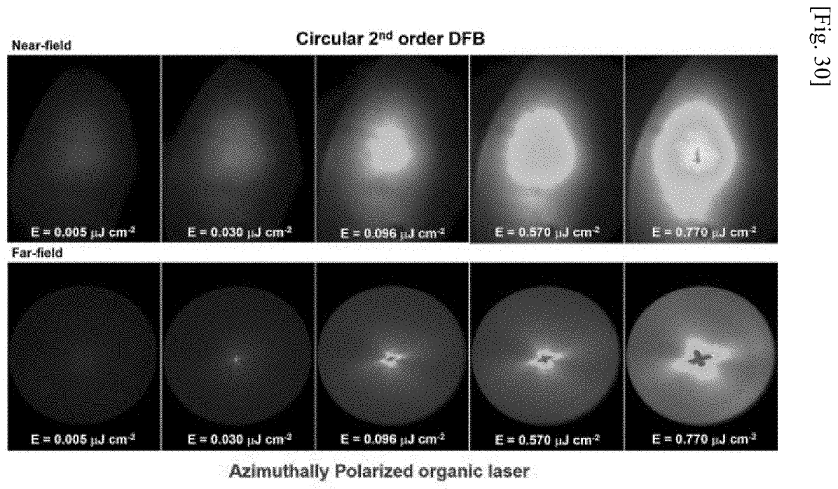

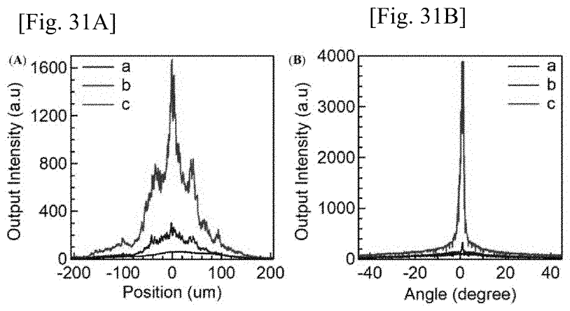

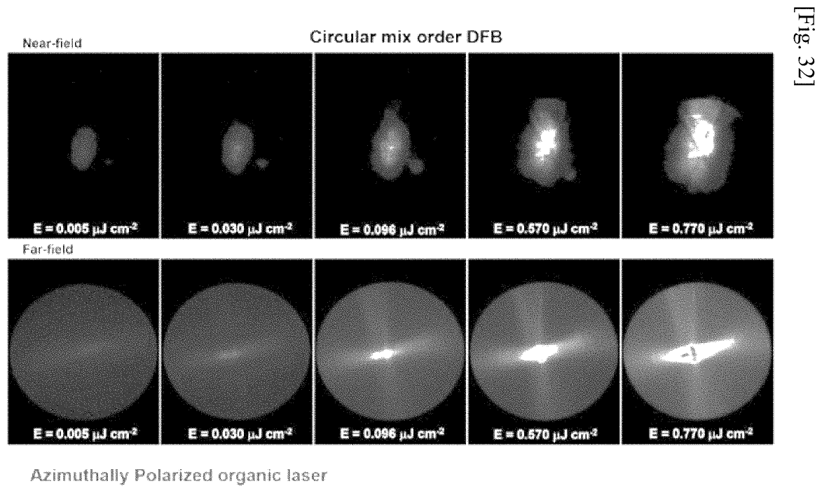

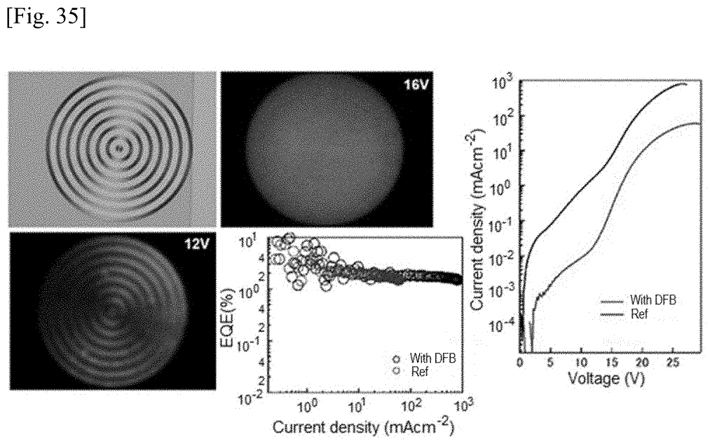

The measurement results under optical pumping are shown in FIGS. 27-33. The measurement results of the electrically driven organic semiconductor laser diodes are shown in FIG. 35. FIG. 27(A) and (B) show emission spectra under optical pumping and FIG. 27(C) and (D) show photonic stop band for waveguide mode. FIG. 28 shows emission intensity versus excitation intensity under optical pumping. FIG. 29(A) and (B) show polarization dependence of the laser emission spectra. and FIG. 29(C) and (D) show emission intensity as a function of polarization angle under optical pumping, FIG. 30 shows near and far-field beam images under optical pumping for circular 2nd order-DFB. FIG. 31(A) shows near-field, FIG. 31(B) shows far-field beam cross-sections of under optical excitation below threshold (a), near threshold (b), and above threshold (c) for circular 2nd order-DFB. FIG. 32 shows near and far-field beam images under optical pumping for circular mixed order-DFB, FIG. 33(A) shows near-field and FIG. 33(B) shows far-field beam cross-sections of under optical excitation below threshold (a), near threshold (b), and above threshold (c) for circular mixed order-DFB. FIG. 35 shows microscope images of and organic circular DFB laser with and without driving; current density-voltage (J-V) curves for devices with and without circular DFB; and external quantum efficiency versus current density in the OLED with and without DFB.

### (Characterization of DFB Grating Structures)

FIG. 36 shows SEM images of DFB grating structures in the organic semiconductor laser diodes manufactured above. FIG. 36(A) shows 2nd order square lattice-DFB, FIG. 36(B) shows mixed order square lattice-DFB, FIG. 36(C) shows 2nd order 2D-DFB, FIG. 36(D) shows mixed order 2D-DFB, FIG. 36(E) show 2nd order circle lattice-DFB, FIG. 36(F) shows mixed order circle lattice-DFB, and FIG. 36(G) shows 2nd order circle 2D-DFB. Laser oscillation was observed from all of Laser Diodes (A)-(G).

Laser emission wavelength (λ_{DFB}), amplified spontaneous emission threshold (Eth) and full width at half maximum (FWHM) of each of Laser Diodes (A)-(C), (E) and (F) are shown in Table 1. Comparison of Laser Diode (B) and Laser Diode (F) indicates six-fold reduction of lasing threshold from circular grating. Further reduction of lasing threshold from a current-driven organic semiconductor would be possible through proper design and choice of the resonator and organic semiconductor to suppress losses and enhance coupling.

TABLE 1

| | λ_{DFB} | Eₜₕ | FWHM |
|---|---|---|---|
| | (nm) | (μ J/cm²) | (nm) |
| Laser Diode (A) | 475 | ~0.04 | 0.30 |
| Laser Diode (B) | 479 | 0.09 | 0.18 |
| Laser Diode (C) | 477 | ~0.02 | 0.28 |
| Laser Diode (E) | 477 | ~0.03 | 0.28 |
| Laser Diode (F) | 478 | ~0.015 | 0.27 |

### Near Infrared Solution-Processed Organic Laser Diode

The present invention also relates to a near infrared solution-processed organic laser diode.

### SUMMARY OF THE INVENTION

We fabricated the first electrically-pumped organic semiconductor laser diode emitting in the near infrared region. The organic active gain material was deposited into thin films using a spin-coating technique. This is the first time that a solution-processing method is used to prepare the OSLD devices. Another important point is the fact that it is the first time a multilayer organic structure is used in OSLD, showing that organic hetero-interfaces can be used for this type of devices.

Such NIR laser diodes are of interest for a variety of applications including biometric authentication (facial, retina and iris recognition), optical interconnects and telecommunication as well as healthcare and photodynamic therapy devices. They are also of interest for retina displays (for bank and security systems), biosensors as well as eye tracking devices for AR glasses/VR headsets, for automative integrated into OLED displays.

It should be emphasized that, because they are compatible with OLED display technology, NIR OSLDs are particularly well-suited for biometric authentication.

The fact that our NIR OSLDs were fabricated by spin-coating the organic gain medium indicates that this technology is compatible with solution-processing fabrication methods such as inkjet printing and thus with printable electronic technologies.

### Overview and Problems of Conventional Technology

Inorganic light-emitting diodes and inorganic laser diodes emitting in the near infrared region are used as a light source in a large variety of applications. For instance, near infrared inorganic vertical-cavity surface-emitting lasers (VCSEL) are used for 3D facial recognition in smartphones. However, many complicated and high-cost processes are required for the fabrication of inorganic semiconductor devices. In addition, these materials need the use of rare metals such as Ga and In, they are not mechanically flexible/stretchable/conformable and cannot be prepared onto curved substrates. These devices lack of optical transparency and are not biocompatible. Finally, it is important to mention that this technology is not compatible with the OLED and organic electronic platform; they are manufactured using different fabrication techniques. The most effective way to solve these issues would be the realization of an organic semiconductor laser diode emitting in the near infrared region.

OSLDs have been recently demonstrated for the first time by Sandanayaka et al. The devices used BSBCz thin films as gain medium and a variety of DFB gratings (2^{nd} order, 1^{st} order, mixed order, 1D and 2D, circular). These devices have emitted only in the blue region of the spectrum so far and were fabricated entirely by thermal evaporation. In addition, these BSBCz devices (based on Cs-doped BSBCz and BSBCz layers) did not use a multilayer of organic materials in order to avoid any potential accumulation of charges at the hetero-interfaces. It is believed that such multilayers, which are extensively used in highly-efficiency OLEDs to optimize the charge balance and exciton confinement, would be detrimental for the devices operating at high current density.

### Issues to be Solved by the Invention

Three main issues are solved in the present invention. First, we demonstrate the first electrically-pumped organic semiconductor laser diode emitting in the near infrared region. Second, our devices are also the first organic laser diodes in which the organic gain medium is deposited into thin film by a spin-coating technique. The third issue to be solved is related to the fact that organic multilayer structures are suitable for OSLDs.

### DETAILED DESCRIPTION OF THE INVENTION

Near infrared TADF OLEDs with a maximum external quantum efficiency of nearly 10% were achieved using a borondifluoride curcuminoid derivative as emitter (Patent WO 2018/155724 A1; Nature Photon. 2018, 12, 98). This dye exhibits excellent TADF activity when blended into a CBP host and low amplified spontaneous emission (ASE) threshold. The remarkable photophysical properties of this compound (good TADF together with good ASE properties) were explained by its large oscillator strength and a nonadiabatic coupling effect between low lying excited states. We also previously demonstrated continuous-wave lasing under optical pumping from an organic laser containing a film of curcuminoid derivative in CBP host which was spin-coated on top of a mixed order DFB grating. In parallel, we previously fabricated electrically-pumped blue organic laser diodes containing a BSBCz thin film as gain medium and DFB resonator structures. (Patent WO2018147470A1) In this context, aiming at realizing a near infrared organic laser diode, we used the NIR curcuminoid derivative as emitter together with a mixed order DFB grating.

Based on our previous results, the 6 wt. % CBP blend used as near infrared emitting layer in conventional OLEDs shows an external quantum efficiency as high as 10%, due to the TADF properties of the curcuminoid derivative. However, the device shows a strong efficiency rolloff at high current density, implying that this CBP blends might not be suitable for laser diode. We confirmed this latter point experimentally. To solve this issue, we used a blend containing a low doping concentration of the near infrared emitting curcuminoid derivative in a F8BT host. The highest photoluminescence quantum yield (45%), the lowest amplified spontaneous emission threshold (1.5 μJ/cm²), and, in an OLED, the maximum external quantum efficiency of 2.2% were obtained in the optimized F8BT blend film with a doping concentration of 1 wt. %. The external quantum efficiency of 2.2% is lower than the best values measured in CBP blend. This is due to the fact that the triplet energy of the F8BT host is lower than the triplet energy of the near infrared emitting dye. This implies that the triplet excitons formed in the near infrared dyes are energy transferred and quenched by the host molecules, resulting in the suppression of the TADF activity. Although external quantum efficiency of the F8BT blends is lower than in the CBP blends because of the suppression of the TADF activity, the quenching of the triplets by the host material must be related to the suppression of the singlet-triplet annihilation, which is presumably responsible for the efficiency rolloff in CBP blends.

In this application, we fabricated a near infrared organic laser diode by combining the 1 wt. % F8BT blend with a mixed-order DFB grating incorporated into an OLED architecture.

### Examples

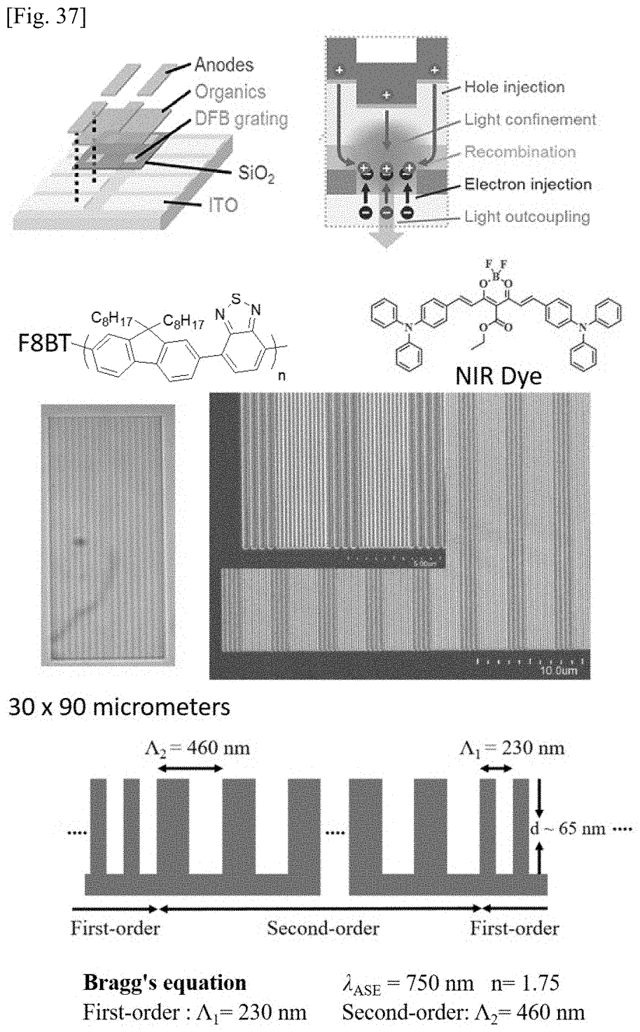

The architecture of the near infrared OSLDs is similar to the mixed order DFB BSBCz devices. First, a sputtered layer of SiO₂ on indium tin oxide (ITO) glass substrates was engraved with electron beam lithography and reactive ion etching to create the mixed order DFB gratings with an area of 30×90 μm. We designed the mixed order DFB gratings to have an alternation of first and second-order Bragg scattering regions that provide optical feedback and efficient outcoupling of the laser emission, respectively. Grating periods of 230 nm and 460 nm were selected for the first and second-order regions, respectively, based on the Bragg condition, mλ_{Bragg}=2 n_{eff} Λₘ, where m is the order of diffraction, λ_{Bragg} is the Bragg wavelength, which was set to the maximum gain wavelength for the curcuminoid derivative (selected here to be around 805 nm), and n_{eff} is the effective refractive index of the structure, which was determined to be 1.75. Information about the device architecture are summarized in FIG. 37.

After preparing the mixed-order SiO₂ DFB gratings on top of the ITO electrodes, 45 nm thick PEDOT:PSS layers were spin-coated on top of the substrates. The PEDOT:PSS layers were then annealed at 180 C in air. The 1 wt. % F8BT blends were spin-coated on top of PEDOT from a chloroform solution. The typical thickness of the emissive layers was 200 nm. The 10 nm thick DPEPO and 55 nm thick TPBI layers were then deposited by thermal evaporation. To complete the devices, cathodes consisting of 1 nm thick LiF and 100 nm thick Al layers were thermally evaporated on top of the TPBI layers through shadow masks. The active area was defined by the DFB gratings. To prevent degradation effects due to oxygen and moisture, the devices were encapsulated in a glove box filled with nitrogen.

The current density-voltage (J-V) characteristics of the OSLDs were measured under pulsed conditions (voltage rectangular pulses of 400 ns and a repetition rate of 1 kHz) at ambient temperature. Though some current flows through the areas above the grating (˜20% based on simulations), most flows through the areas above the exposed ITO. For simplicity and consistency, the exposed ITO area was used for the calculation of current density for all OSLDs, though this may lead to slight overestimations. To measure the EL spectra, emitted laser light from OSLDs was collected normal to the device surface with an optical fiber connected to a multichannel spectrometer (PMA-50, Hamamatsu Photonics) and placed 3 cm away from the device. The J-V-luminance characteristics under pulse driving were measured with an amplifier (NF, HSA4101) and a photomultiplier tube (PMT) (C9525-02, Hamamatsu Photonics). Both the PMT response and the driving square wave signal were monitored on a multi-channel oscilloscope (Agilent Technologies, MSO6104A).

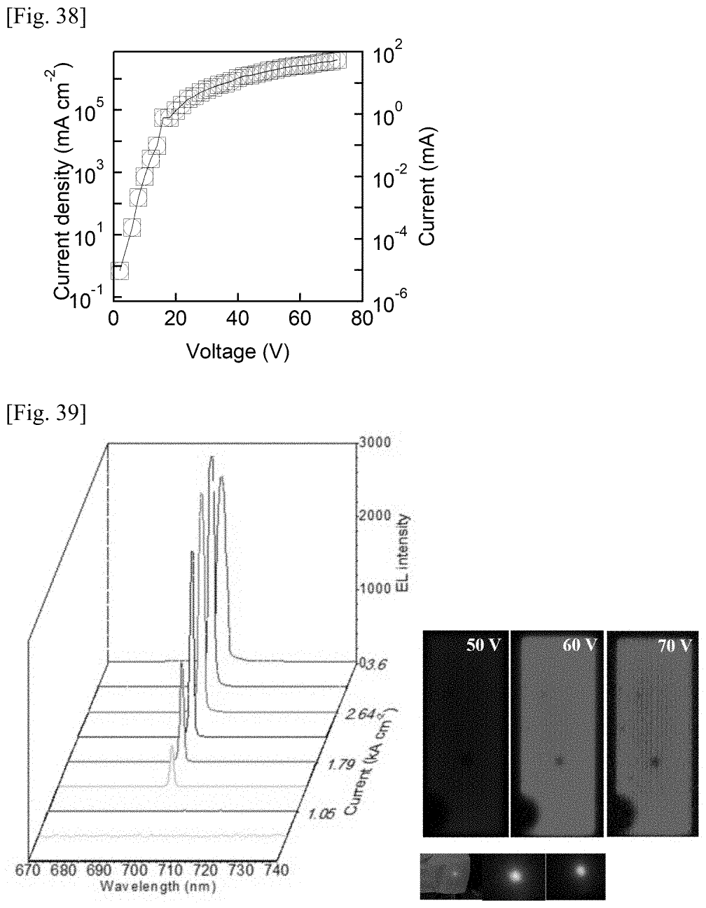

FIG. 38 displays the J-V curve of the device under applied pulsed voltage condition (400 ns, 1 kHz). It can be seen that current as high as 100 mA and current densities higher than 1 kA/cm² can be injected in the devices. It is essential to be able to inject such a high current density in order to achieve current injection lasing.

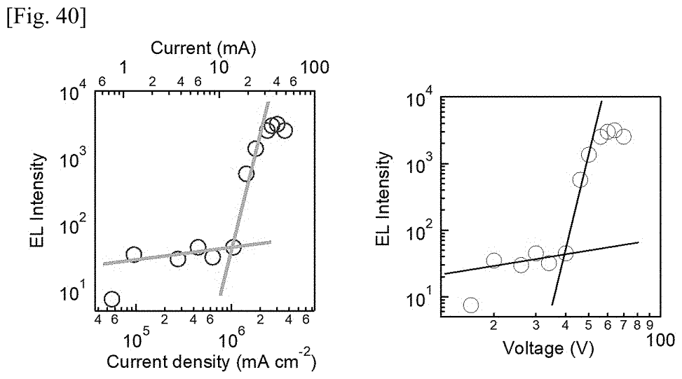

FIG. 39 shows the evolution of the emission spectra as a function of the current density. It can be seen that a lasing peak at 705 nm can be observed for current densities higher than the current lasing threshold of 1 kA/cm². In addition to the pictures of the OSLDs under pulsed operation at various applied voltages, some pictures show the well-defined laser beam emitted from the device.

FIG. 40 shows the output electroluminescence intensity measured as a function of either the current density or the applied voltage. The observed change of slopes is used to determine the lasing threshold of about 1 kA/cm². Overall, these results provide an indication of current injection lasing from an OSLD emitting in the NIR region for the first time.

### CONCLUSION

Lasers provide light with unique and useful properties, including high intensity, directionality, monochromatic emission and large coherence length. Due to these properties, lasers have found applications in almost every economic and industrial sector. Lasers are ubiquitous in our everyday life, for example, in scanners, printers and sensors. The ability to control the temporal, spectral, and spatial characteristics of lasers with extreme precision has transformed the fields of spectroscopy, telecommunications and sensing, providing record-breaking sensitivity and resolution. Facilitated by the constant development and rapid improvements of lasers, they also continue to enter new fields including in healthcare/medical devices.

Until now, lasers used for applications are typically based on inorganic light-emitting materials, in many cases inorganic semiconductors and doped crystals. These materials are generally brittle, nonflexible and their production and processing often require highly reactive and toxic heavy metal precursors as well as high vacuum equipment. By contrast, organic semiconductor materials are generally easier to process and the resulting devices can be mechanically flexible/stretchable/patchable. In addition, organic emitter materials are often less harmful than their inorganic counterparts, and devices based on them have shown excellent biocompatibility. They are also full compatible and can be easily integrated onto organic electronic and OLED platforms. A number of classes of organic semiconductors exhibit high optical gain, enabling their use as laser media and optical amplifiers. Due to their facile processability, they are compatible with a large variety of optical resonator structures, and in many cases, the resonator can be inscribed directly into the organic gain medium, leading to versatile and low cost laser structures.

From our perspective, our technology will replace inorganic semiconductor lasers for which the advantages of organic materials can play a crucial role. This implies a variety of applications where mechanical flexibility/stretchability/patchability,/conformability compatibility with OLED and organic electronic platforms, biocompatibility, tunability of the emission wavelength and transparency are critical factors. In particular, we foresee that the NIR OSLD technology reported in the present invention form will be widely used in the future as light source for biometric authentication (including on smartphone and OLED TVs), retina scan for security issues, eye tracking for VR/AR and automative integrated OLED displays. Other types of devices include chemical and biosensors, healthcare and photodynamic therapy devices as well as optical interconnects.

As mentioned above, important advantages of our invention are based on the intrinsic advantages of organic semiconductors compared to their inorganic counterparts. This includes their compatibility with the OLED and organic electronic plartform, biocompatibility, mechanical flexibility/stretchability/patchability/conformability, chemical tunability of the EL and lasing properties together with low-cost and simpler fabrication techniques.

The present invention demonstrates for the first time an OSLD operating in the NIR region. This implies that OSLD technology becomes interesting for other applications than those targeted for visible OSLDs. The present invention has also one very important advantage compared to our previous patents about OSLDs. In our previous invention, the gain medium, i.e. the BSBCz thin film, was prepared by thermal evaporation. This makes our OSLD technology compatible with the current OLED display technology (OLED displays from the main manufacturers are fabricated by thermal evaporation). However, intensive R&D activities not only in academia but also industry are currently working on soluble organic light-emitting materials for printed OLED displays and organic electronic devices. Our present invention demonstrates for the first time the possibility to fabricate OSLDs by solution-processing. This means that our technology is compatible with any printed and solution-processed electronic platforms.

Finally, the last important point demonstrated by our invention is the possibility to achieve electrical lasing from an organic multilayer architecture. Our previous OSLDs were based on the following architecture: ITO (100 nn)/20 wt. % Cs:BSBCz (60 nm)/BSBCz (150 nm)/MoO₃ (10 nm)/Ag (10 nm)/Al (90 nm). Doping the BSBCz film with Cs in the region close to the ITO contact improves the electron injection into the organic layer, and MoO₃ is used as a hole injection layer. While the most efficient OLEDs generally use multilayer architectures to optimize charge balance, it was believed that charges can accumulate at organic hetero-interfaces at high current densities, which is detrimental for device performance and stability. To avoid this issue, the OSLDs contained only BSBCz as the organic layer and were designed to minimize the number of organic hetero-interfaces. While this statement about the accumulation of charges at organic interfaces and its detrimental effects on device stability is right in many cases, our present invention shows that it is still possible in some cases to achieve electrical lasing from an OSLD based on organic multilayer structures. In other words, our invention shows that multilayer organic architectures can be used to optimize charge balance and exciton confinement in OSLDs.

Other remarks which can lead to new claims. (1) This is the first time that the active layer of an OSLD is based on a guest-host polymer system. (2) This is also the first time that an OSLD is based on a blend material where energy transfer of the singlet excitons can take place from host to guest molecules. (3) PEDOT:PSS is widely used in spin-coated OLEDs, solar cells, etc. to improve hole injection in the devices. We demonstrate that PEDOT can be used in OSLDs to improve hole injection. (4) In BSBCz devices, electrons were injected from ITO and the Cs-doped BSBCz (corresponding to what we call an inverted structure). In the present invention, in contrast, holes are injected from the ITO and electrons from the top electrodes, respectively. (5) in the NIR OSLDs fabricated in the present invention, it should be highlighted again that the triplets of the emitters are quenched by the polymer host molecules. Indicates that the use of triplet quenchers can improve the OSLD performances. (6) in the NIR OSLDs fabricated in the present invention, the polymer host is an ambipolar charge transport material.

1. An electrically driven organic semiconductor laser diode comprising a pair of electrodes, an optical resonator structure having a distributed feedback (DFB) structure, and one or more organic layers including a light amplification layer composed of an organic semiconductor, which satisfies one of the following conditions (i) to (iii):
(i) the distributed feedback structure is composed of a first-order Bragg scattering region,
(ii) the distributed feedback structure is composed of a two-dimensional distributed feedback, and
(iii) the distributed feedback structure is composed of a circular distributed feedback.

2. The electrically driven organic semiconductor laser diode according to claim 1, which satisfies Condition (i).

3. The electrically driven organic semiconductor laser diode according to claim 2, which is an edge-emission type.

4. The electrically driven organic semiconductor laser diode according to claim 3, wherein the emission edge is an edge of a glass waveguide having a waveguide length of 50 μm or more.

5. The electrically driven organic semiconductor laser diode according to claim 3, wherein the emission edge is coated with a transparent resin having a thickness in the optical radiation direction of 50 μm or more.

6. The electrically driven organic semiconductor laser diode according to claim 1, which satisfies Condition (ii).

7. The electrically driven organic semiconductor laser diode according to claim 1, which satisfies Condition (iii).

8. The electrically driven organic semiconductor laser diode according to claim 7, wherein the distributed feedback structure has a lattice structure.

9. The electrically driven organic semiconductor laser diode according to claim 6, wherein the distributed feedback structure has a mixed structure of DFB grating structures differing in point of the order relative to laser emission wavelength.

10. The electrically driven organic semiconductor laser diode according to claim 9, wherein the mixed structure is composed of a first-order Bragg scattering region and a second-order Bragg scattering region

11. The electrically driven organic semiconductor laser diode according to claim 10, wherein the second-order Bragg scattering region is surrounded by the first-order Bragg scattering region.

12. The electrically driven organic semiconductor laser diode according to claim 10, wherein the first-order Bragg scattering region and the second-order Bragg scattering region are formed alternately.

13. The electrically driven organic semiconductor laser diode according to claim 1, which satisfies Conditions (ii) and (iii).

14. The electrically driven organic semiconductor laser diode according to claim 1, wherein the organic semiconductor contained in the light amplification layer is amorphous.

15. The electrically driven organic semiconductor laser diode according to claim 1, wherein the molecular weight of the organic semiconductor contained in the light amplification layer is 1000 or less.

16. The electrically driven organic semiconductor laser diode according to claim 1, wherein the organic semiconductor contained in the light amplification layer is a non-polymer.

17. The electrically driven organic semiconductor laser diode according to claim 1, wherein the organic semiconductor contained in the light amplification layer has at least one stilbene unit.

18. The electrically driven organic semiconductor laser diode according to claim 1, wherein the organic semiconductor contained in the light amplification layer has at least one carbazole unit.

19. The electrically driven organic semiconductor laser diode according to claim 1, wherein the organic semiconductor contained in the light amplification layer is 4,4′-bis[(N-carbazole)styryl]biphenyl (BSBCz).

20. The electrically driven organic semiconductor laser diode according to claim 1, which has an electron injection layer as one of the organic layers.

21. The electrically driven organic semiconductor laser diode according to claim 20, wherein the electron injection layer contains Cs.

22. The electrically driven organic semiconductor laser diode according to claim 1, which has a hole injection layer as an inorganic layer.

23. The electrically driven organic semiconductor laser diode according to claim 22, wherein the hole injection layer contains molybdenum oxide.

24. The electrically driven organic semiconductor laser diode according to claim 1, wherein the concentration of the organic semiconductor contained in the light amplification layer is 3% by weight or less.

25. A method for producing electrically driven OSLD chips, comprising:
forming two or more electrically driven OSLD chip laminates each containing a pair of electrodes and plural layers sandwiched between the electrodes on a substrate, as spaced from each other thereon, and
cutting the substrate via the space between the laminates to give electrically driven OSLD chips each composed of the laminate and the substrate.

26. The method according to claim 25, wherein the electrically driven OSLD chips each have a distributed feedback structure composed of a first-order Bragg scattering region.

27. The method according to claim 25, wherein the electrically driven OSLD chips are edge-emission type ones.

28. The method according to claim 27, wherein the emission edge is an edge of a glass waveguide having a waveguide length of 50 μm or more.

29. The method according claim 25, wherein after the cutting, at least a part of the electrically driven OSLD chip is coated with a resin.

30. The method according to claim 29, wherein the resin is a transparent fluororesin.

31. An OSLD operating in the NIR spectral region.

32. An OSLD produced using a solution-processing technique.

33. An OSLD having an active layer of a guest-host polymer system.

34. A current injection lasing from an organic multilayer architecture.

35. A current injection lasing from a blend in which energy transfer of singlet excitons can be transferred via Forster mechanism from host molecules to guest molecules.

36. A method for using triplet quencher in OSLDs.

37. An emissive layer of an OSLD based on an ambipolar charge transport host material.

38. An OSLD with a non-inverted architecture.

39. A method for using PEDOT:PSS as hole injection layer in OSLDs.

40. An organic laser diode utilizing a TADF laser dye.

41. An organic laser diode utilizing a light-emitting compound with long photoluminescence lifetime.
